(19) United States
(12) Patent Application Publication
(10) Pub. No.: US 2001/0005149 A1
(43) Pub. Date: Jun. 28, 2001

(54) Read-only sequence controller

(76) Inventor: Yoshikazu Kuze, Tokyo (JP)

Correspondence Address: DENNISON, MESEROLE, SCHEINER & SCHULTZ, Suite 612, 1745 Jefferson Davis Highway, Arlington, VA, 22202, US

(21) Appl. No.: 09/725,954

(22) Filed: Nov. 30, 2000

(30) Foreign Application Priority Data
Nov. 30, 1999 (JP) 11-376041

(51) Int. Cl. G11C 29/00

(52) U.S. Cl. 327/1; 365/200

(57) ABSTRACT

A read-only sequence controller has a master circuit mounted on a housing and having a first presettable counter for producing an instruction pulse, and a slave circuit having a second presettable counter for setting a cycle, and a pules the generating circuit for producing a plurality of pulses at the cycle in response to the instruction pulse from the master circuit. An EPROM is provided for storing a machine operating program data and for producing a program data in response to the pulses fed from the slave circuit. There is provided a plurality of output relays operated in accordance with the program data fed from the EPROM, and a plurality of terminal connected to the relays. The output terminals are arranged in two rows at one of sides of the housing.

### BACKGROUND OF THE INVENTION

The present invention relates to a compact read-only sequence controller.

FIG. 12 shows an external appearance of a conventional sequence controller by the applicant of this present patent application.

Referring to FIG. 12, the conventional read-only sequence controller has an output relay unit 43. The output relay unit 43 comprises eight relays 44 provided for eight external machines and arranged in two rows, and output terminal units 45 and 46 mounted on the output relay unit 43. The terminal unit 45 comprises four sets of terminal, namely eight terminals in total, for four relays, because each relay has two terminals, terminal unit 46 has ten terminals for the other four relays and for an alternating current input terminals X, Y.

The terminal X is connected to an input terminal of each relay 44. An output terminal of each relay 44 is connected to the output terminal 45a of the terminal unit 45 or an output terminal 46a of the terminal unit 46. Furthermore, the terminal Y is connected to the terminal 45b or 46b.

The sequence controller is attached to a process machine such as a press. Since the terminal units 45 and 46 are disposed on both sides of the relay unit 43, the wiring among the relay unit 43 and the terminal units 45 and 46, and the process devices of the process machine are extremely complicated.

In addition, an operator for operating the process machine must go to the sequence controller and must operate various switches such as a power switch 47, start switch 48, reset switch 49 and others at the occurring of abnormality of the process machine.

This causes the operability and the manufacturability of the process system to reduce.

### SUMMARY OF THE INVENTION

An object of the present invention is to provide a sequence controller, in which the wiring between the relay unit and the terminal unit may be simplified.

Another object of the present invention is to provide a sequence controller which may be easily and effectively operated.

According to the present invention, there is provided a read-only sequence controller for controlling operation of a machine, comprising a master circuit mounted on a housing and having a first presettable counter for producing an instruction pulse, a slave circuit having a second presettable counter for setting cycle, and a pulse generating circuit for producing a plurality of pulses at the cycle in response to the instruction pulse from the master circuit, an EPROM storing a machine operating program data and for producing a program data in response to the pulses fed from the slave circuit, a plurality of output relays operated in accordance with the program data fed from the EPROM, a plurality of output terminals connected to the relays.

The output terminals are arranged in two rows at one of sides of the housing.

The controller further comprises a reset switch and a start switch provided at a position remote from the controller for resetting devises in the controller and for starting controller.

These and other objects and features of the present invention will become more apparent from the following detailed description with reference to the accompanying drawing.

### BRIEF DESCRIPTION OF DRAWINGS

FIG. 1 is a plan view of a read-only sequence controller according to the present invention;

FIG. 2 shows a circuit of an output relay unit board;

FIG. 3 is a front view of the controller of FIG. 1;

FIG. 4a is a partially sectional side view of the sequence controller as viewed from an arrow IV in FIG. 1;

FIG. 4b is a side view of a connector in FIG. 4a;

FIG. 4c is a plan view of FIG. 4b;

FIG. 5 shows a pulse control unit board connected to an AC/DC converter;

FIG. 6 is an enlarged plan viewed of the pulse control unit board;

FIG. 7 is a side view as viewed from the arrow IV of FIG. 1;

FIG. 8 shows eight electromagnetic valves;

FIG. 9 is a side view as viewed from an arrow IX of FIG. 1;

FIG. 10 shows a circuit of a conventional control unit which is a granted patent in the U.S. to the applicant of the present invention; and

FIG. 11 shows the circuit of FIG. 10 a part of which is surrounded by a bold line;

FIG. 12 is a plan view of a conventional sequence controller.

### DETAILED DESCRIPTION OF THE PREFERRED EMBODIMENTS

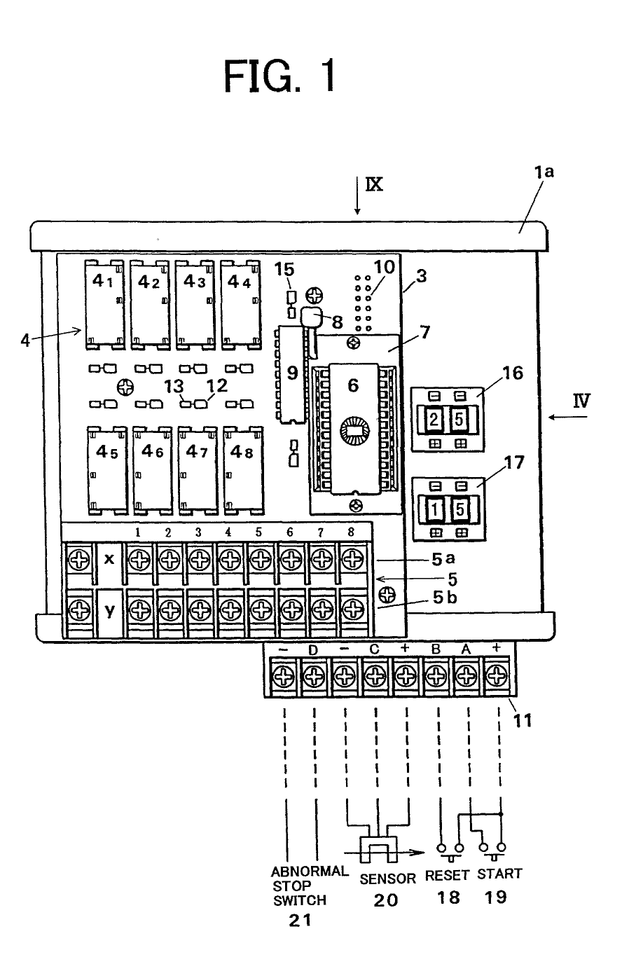

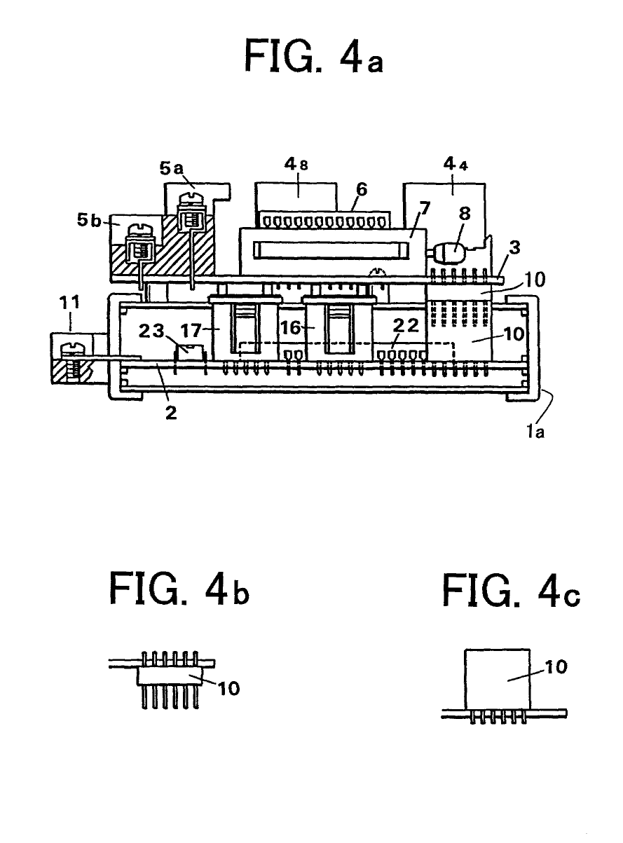

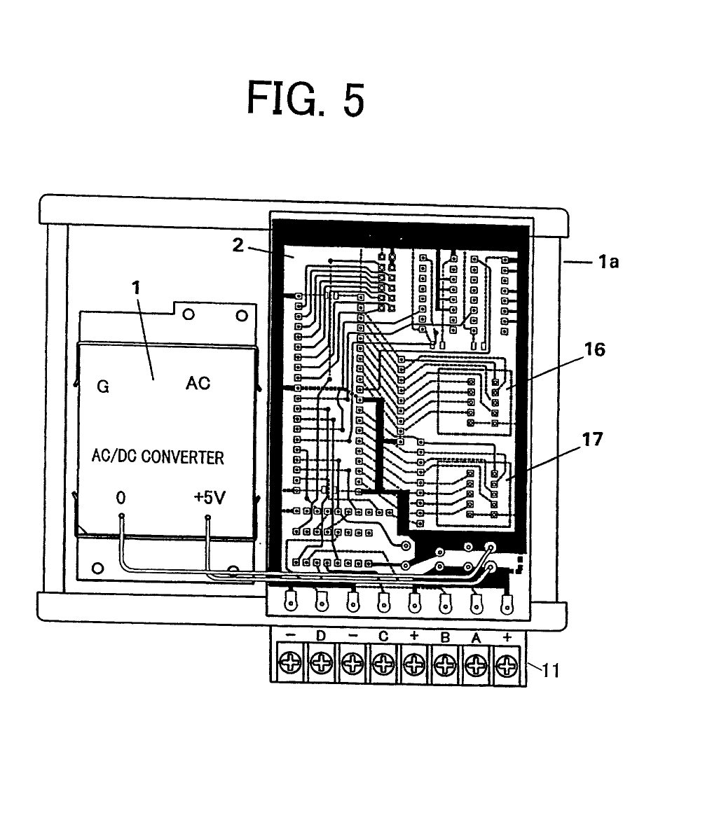

Referring to FIGS. 1, 4a and 5 a read-only sequence controller of the present invention comprises a clock pulse control unit substrate 2 which is mounted in a housing 1a as shown in FIG. 4a, and connected to an AC/DC converter 1 (FIG. 5) for DC 5V, and an output relay unit substrate 3 mounted on the housing 1a. An output relay unit 4 comprising eight relays 4₁ through 4₈ for operating eight process devices provided in a processing machine and an output terminal unit 5 are mounted on the output relay unit substrate 3. The terminal unit 5 is arranged in two rows comprising upper eight output terminals 5a and the alternating current input terminal X, and lower eight output terminals 5b and the alternating current input terminal Y. The output terminals 5a and 5b are arranged in two rows in plan view of FIG. 1 and disposed at an upper position and a lower position as shown in FIG. 4a. An EPROM 6 in which program data for the processing the processing machine are written beforehand, is detachably fixed to a connector 7 by a lock lever 8.

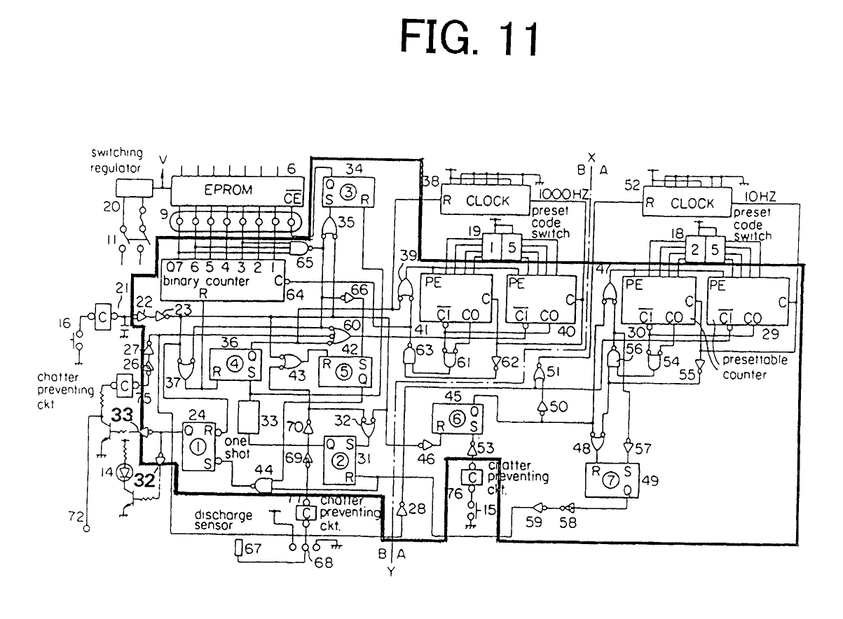

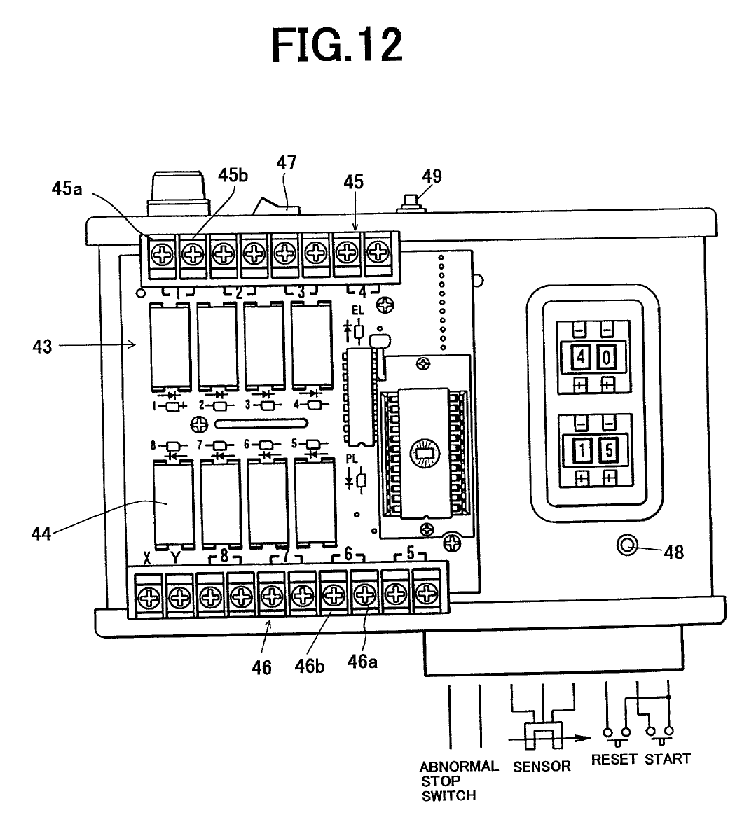

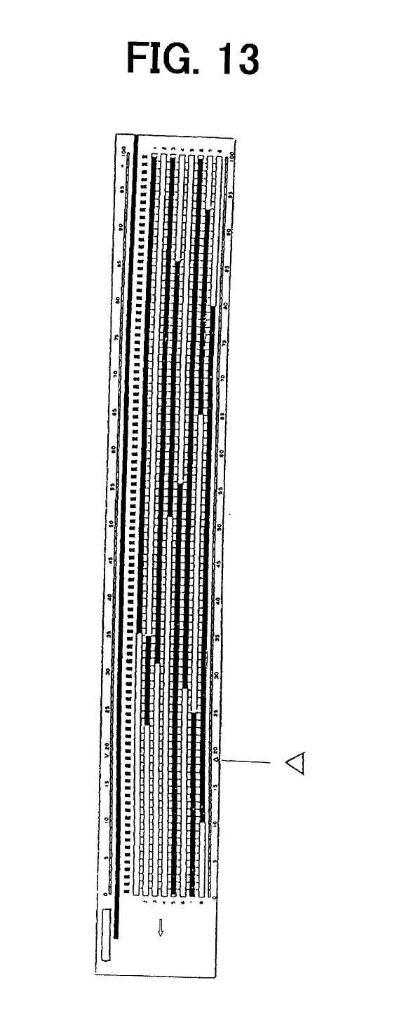

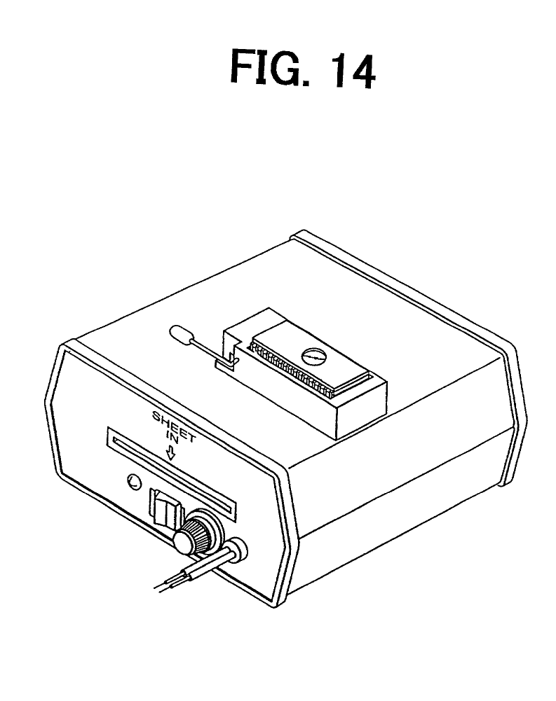

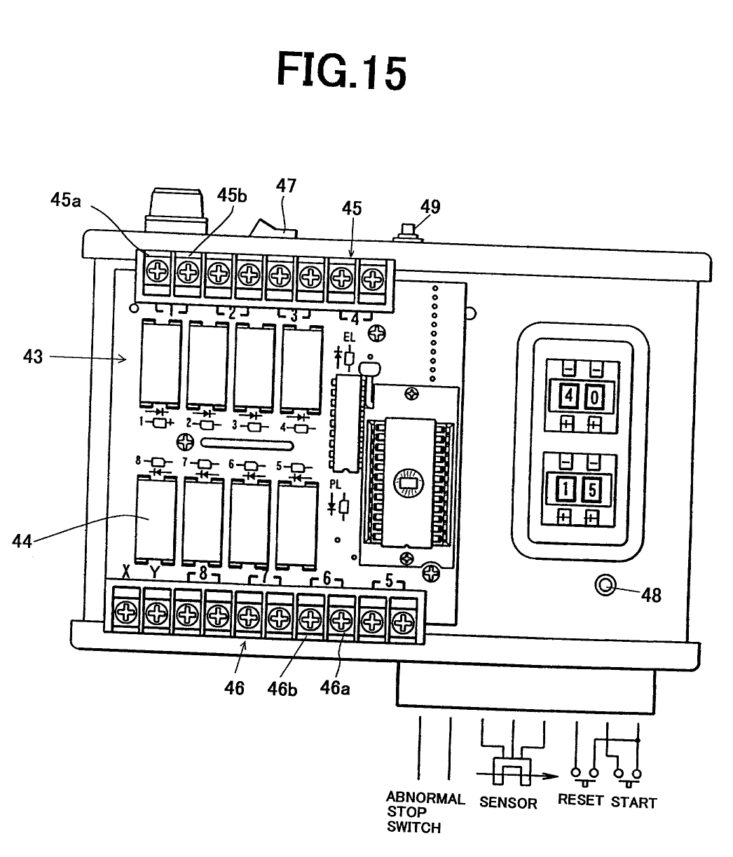

The sequence controller further comprises a transistor array 9 connected to the EPROM 6 for operating the relays 4, and a metal connector 10 provided for connecting circuits on the clock pulse control unit substrate 2 and the output relay unit substrate 3. Eight LEDs 12, 13 are provided for displaying the operation of the eight relays. There are provided with an abnormality LED 15 which is lighted when an abnormality occurs, preset code switch 16 of a preset code counter for a master circuit A (a right side of a line X-Y of FIG. 11), and a preset code switch 17 of a preset code counter for a slave circuit Y (a left side of the line X-Y).

The preset code switch 16 displays a two-digit number for one cycle time and is adapted to select a necessary cycle time. In the present embodiment, one cycle time is 0.1 second and the number of “25” is set at the preset code switch 16. The number of 25 signifies a cycle time of 2.5 seconds. Similarly, the preset code switch 17 displays the number of “15” which signifies a cycle time of 1.5 seconds. Although the cycle time of the slave circuit B is generally set at 1.5 seconds, with consideration to the longevity of the machine and die, if there is still a room in the cycle time of the master circuit A, it is advantageous to increase the cycle time to 4.0 seconds.

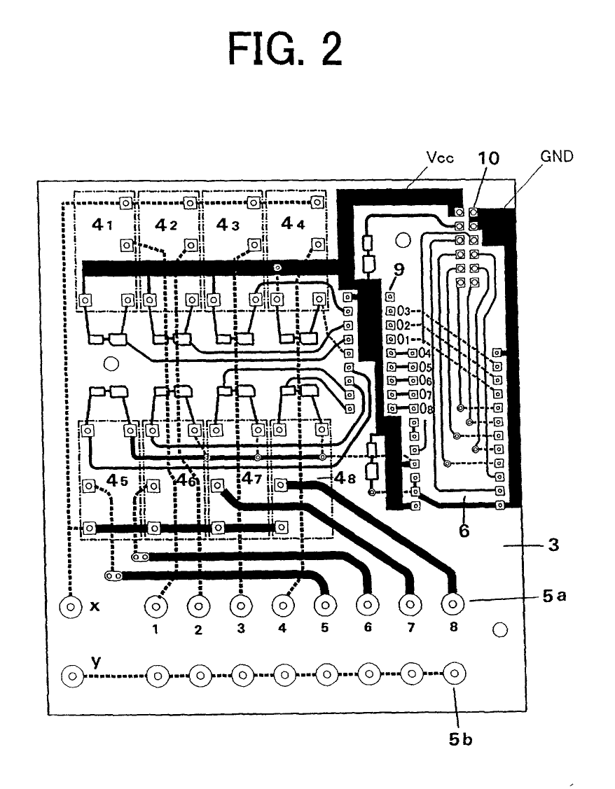

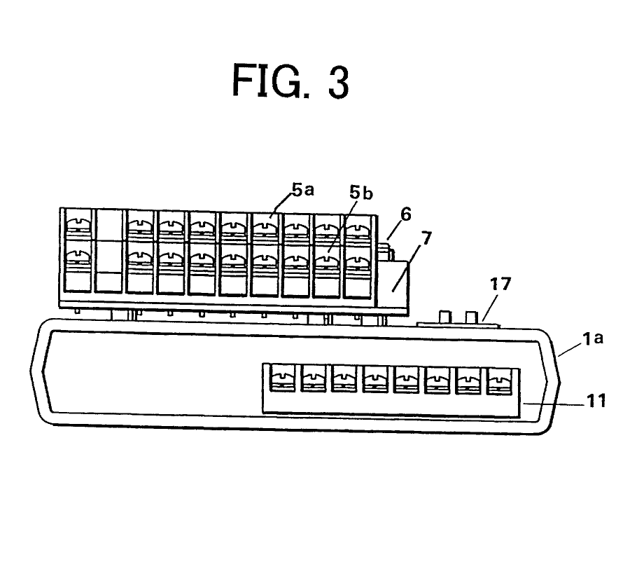

Referring to FIG. 2 showing the circuit of the output relay substrate 3, outputs O₃, O₂, O₁, O₄, O₅, O₆, O₇, O₈ of the EPROM 6 are connected with relays 4₃, 4₂, 4₁, 4₄, 4₅, 4₆, 4₇, 4₈ through the transistor array 9.

An output terminal of each relay 4 from the terminal X is connected to a corresponding upper terminal 5a, and the terminal Y is connected to lower terminals 5b.

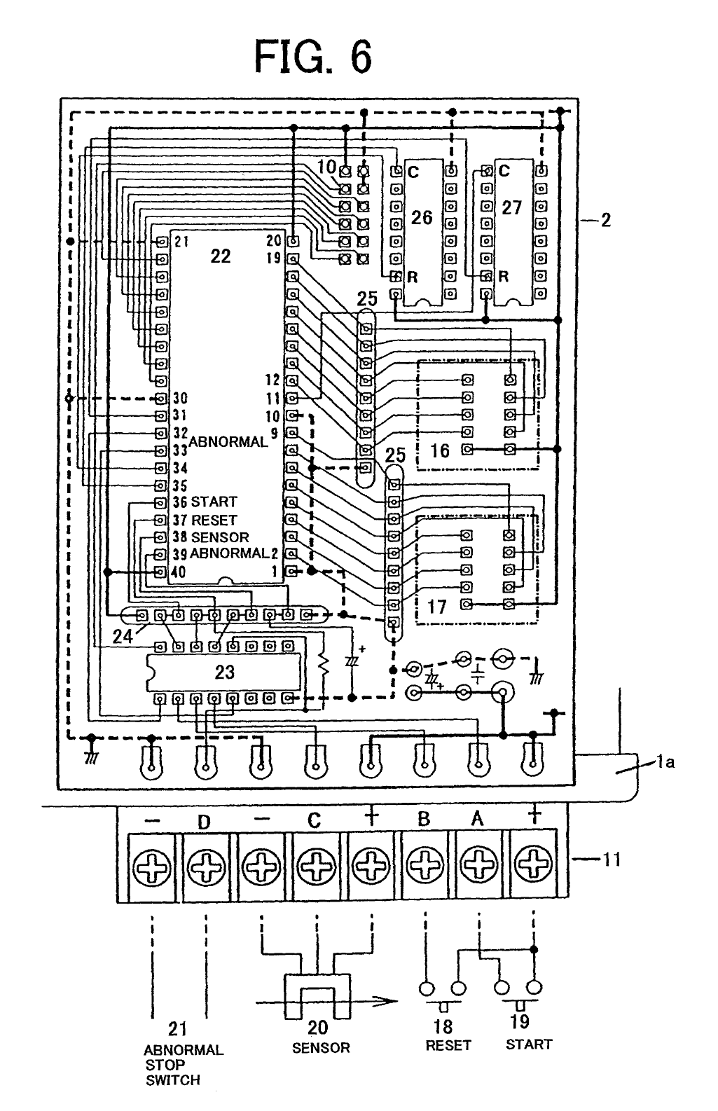

FIG. 6 shows a circuit constructed around a gate array 22 having 40 pins. The gate array 22 is made into CMOS-IC, and comprises a plurality of gates for processing input signals and controlling relays 4.

In FIG. 6, the pins 2 through 9 of the gate array 22 are connected to the preset code switch 17 of the slave circuit, the pins 12 to 19 to the preset code switch 16 of the master circuit, pins 22 to 29 to the EPROM 6 through the metal connector 10. A clock output terminal C of a clock pulse generating circuit 26 of the master circuit is connected to a pin 35 of the gate array, while a reset terminal R is connected to a pin 34. A clock output terminal C of a clock pulse generating circuit 27 of the slave circuit is connected to a pin 11, while a reset terminal R is connected to a pin 31. The thirty-four pins of the gate array 22, excluding six pins for positive and negative terminals of the power source, are connected one to one to respective external functional parts through parallel printed wiring at minimum distances.

A transistor array 23 is disposed before a chatter killer array 24 which is disposed before the gate array 22. Thus, the input impedance of the gate array 22 is decreased.

An input output terminal board 11 is projected from the housing 1a at a lower position than the output terminal unit 5 as shown in FIG. 4a. The terminal board 11 has four sets of terminals A, B, C and D. The terminal set D is connected to an abnormal stop switch 21 of the process machine, the terminal set C is connected to a sensor 20 provided at a product outlet of the machine for detecting the discharge of a product. The terminal sets B and A are connected to a reset switch 18 and a start switch 19 provided at a proper position such as a pillar where the operator is easily accessible.

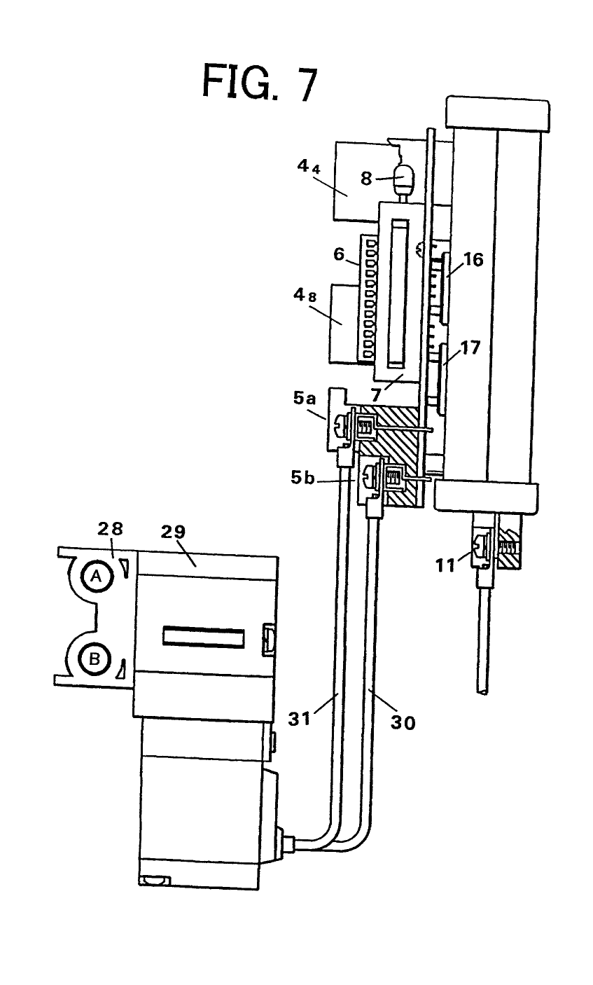

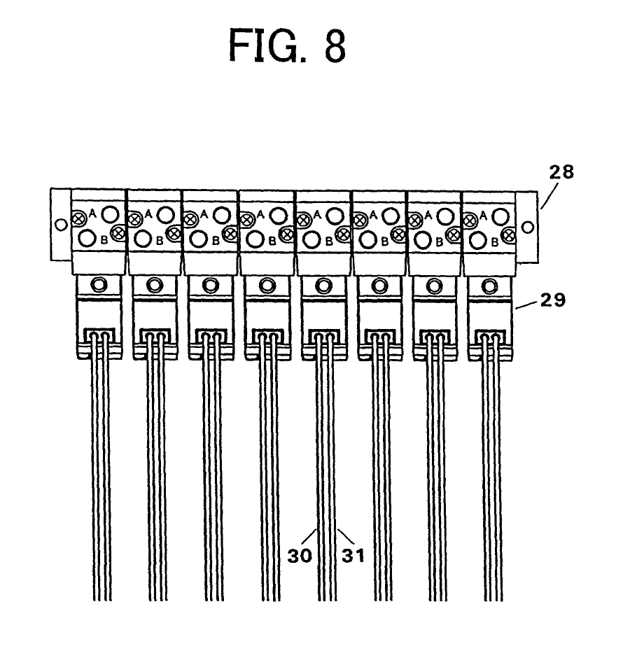

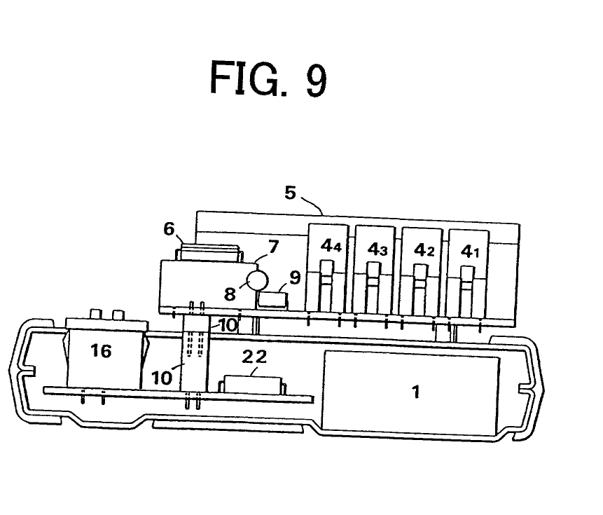

Referring to FIGS. 7 and 8, each terminal of the upper terminal 5a and lower terminal 5b is connected to one of eight electromagnetic valves 29 by cables 30 and 31. Ports A, B of a manifold 28, which are communicated with the electromagnetic valve 29, are communicated with a pneumatic cylinder mounted on the processing machine for operating the machine.

In operation, the clock pulse generating circuit 16 of the master circuit A produces an instruction pulse. The instruction pulse is applied to the clock pulse generating circuit 17 of the slave circuit B to start the one cycle operation.

When a command one pulse generated at the master circuit is applied to the slave circuit, the slave circuit operates the relays 4 for operating the processing machine in accordance with the program stored in the EPROM 6. Accordingly the machine performs an operation of one cycle in accordance with the program. When the operation of one cycle is completed, the machine is stopped by a signal from the slave circuit. When the sensor 20 disposed at the outlet of the machine detects the passage of a product, a signal from the sensor 20 is fed to the terminal set C of the input terminal 11, and the signal is applied to a pin 38 of the gate array 22 through a transistor of the transistor array 23 and a chatter killer circuit of the chatter killer array 24, so that the machine is restarted after the next command one pulse from the master circuit is applied.

If there is an abnormality so that the sensor 20 does not generate the signal although the slave circuit completes the one cycle, abnormality signals are simultaneously generated at pins 32 and 33 of the gate array 22. Namely, the abnormality signal from the pin 32 of the gate array 22 of FIG. 6 is applied to the abnormality indicating LED 15 (FIG. 1) through a transistor of the transistor array 23 and the metal connector 10 to light the LED 15. At the same time, the signal from the pin 33 is applied to an abnormality stop pin 39 through a transistor of the transistor array 23, and a chatter killer circuit of the chatter killer array 24, so that the clock pulse generating circuit 26 stops generating the pulse, thereby stopping the operation of the machine due to the abnormality.

After the abnormality is checked and repaired, the reset switch 18 is pressed. Hence a reset signal is applied to a pin 37 of the gate array 22 through a transistor of the transistor array 23 and a chatter killer circuit of the chatter killer array 24. Thereafter, the start switch 19 is pressed. A start signal is hence applied to a pin 36 of the gate array 22 through a transistor of the transistor array 23 and a chatter killer circuit of the chatter killer of the chatter killer array 24 to start the machine.

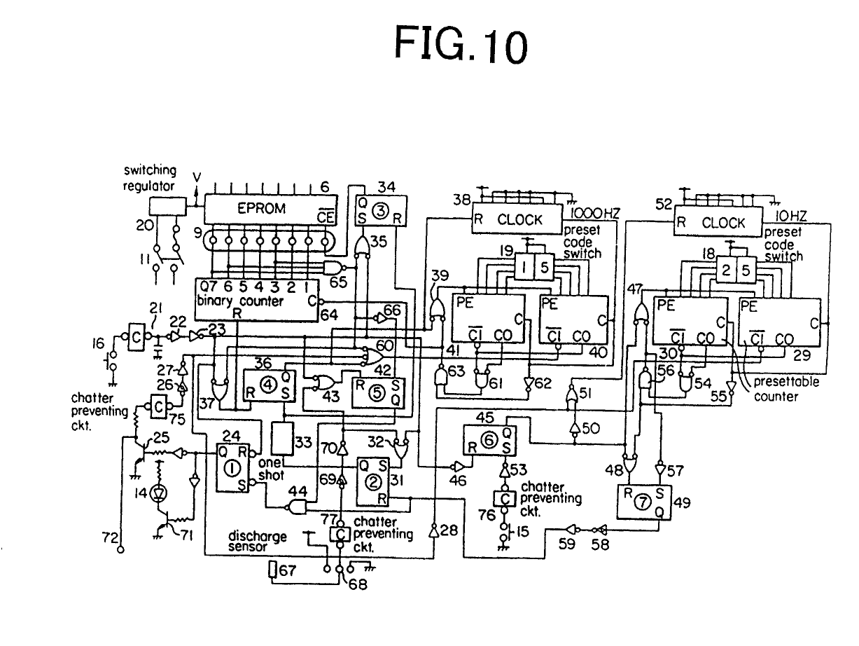

FIG. 10 shows a circuit of a conventional sequence controller, a patent application of the sequence controller has been filed by the inventor of this invention and granted in the United States (U.S. Pat. No. 5,357,422). A portion enclosed by a bold line in FIG. 11 is entirely included in the gate array 22 having forty pins. In FIG. 11 the right side of the dot dash line X-Y is the master circuit A and the left side is the slave circuit B. The numerals 31, 32, 33, 34, 35 of FIG. 11 indicate the positions of corresponding pins of FIG. 6. If an abnormality occurs in the machine so that there is no signal from a sensor 67 of the system of FIG. 11 which is provided at the outlet of the machine, although the slave circuit finished one cycle, a flip-flop \mathring{1} is set. The output Q of the flip-flop \mathring{1} is divided into two, so that the pin 32 and the pin 33 (which are also described in FIG. 11) of the gate array 22 simultaneously generate the abnormal signals.

In accordance with the present invention, output terminals of relays are arranged in two rows at one of sides of the device. Therefore wiring between the relays and terminals is simplified, and cables between the terminals and operating devices of the processing machine can be reduced in length without being detoured. Furthermore, operating switches such as a reset switch and a start switch are disposed at a position where the switch can be easily operated. Thus, the operability and manufacturability of the machine are improved.

Since the output terminals are arranged in two rows in plan view and disposed at an upper position and a lower position, wiring among the relays, terminals and external devices can be properly connected without complicating.

While the invention has been described in conjunction with preferred specific embodiment thereof, it will be understood that this description is intended to illustrate and not limit the scope of the invention, which is defined by the following claims.

What is claimed is:

1. A read-only sequence controller for controlling operation of a machine, comprising:
a master circuit mounted in a housing and having a first presettable counter for producing an instruction pulse;
a slave circuit having a second presettable counter for setting a cycle, and a pulse generating circuit for producing a plurality of pulses in the one cycle in response to the instruction pulse from the master circuit;
an EPROM storing a machine operating program data and for producing a program data in response to the pulses fed from the slave circuit;
a plurality of relays operated in accordance with the program data fed from the EPROM;
a plurality of output terminals connected to the relays, the output terminals being arranged in two rows at one of sides of the housing.

2. The controller according to claim 1 further comprising a plurality of terminals connected to external switches for remotely operating the sequence controller.

3. The controller according to claim 1 wherein the terminals are arranged at the same side of the output terminals.

4. The controller according to claim 1 wherein the output terminals are arranged in two rows in plan view and disposed at an upper position and a lower position.
